(19) United States
(12) Patent Application Publication
(10) Pub. No.: US 2020/0135952 A1
(43) Pub. Date: Apr. 30, 2020

(54) PORTABLE SHINGLED SOLAR MODULES

(71) Applicant: The Solaria Corporation, Fremont, CA (US)

(72) Inventor: Lisong Zhou, Freemont, CA (US)

(21) Appl. No.: 16/174,969

(22) Filed: Oct. 30, 2018

(51) Int. Cl. H01L 31/05; H01L 31/18

(52) U.S. Cl. CPC H01L 31/0504; H01L 31/1876

(57) ABSTRACT

The present disclosure describes a portable solar module including a plurality of strips, each strip including at least one bus bar formed on a top surface thereof. The solar module further includes electrically conductive adhesive electrically connecting each strip when applied to the strip where the strips are arranged to overlap one another to connect the strips in series, and at least one string of overlapped strips, wherein the portable solar module has an output of less than about 130 W and less than about 30V.

### TECHNICAL FIELD

The present disclosure relates to solar modules, and more particularly, to solar cells incorporated into shingled array module (“SAM”), and methods of manufacturing a solar module of bonded solar cells in a shingled array.

### BACKGROUND

Over the past few years, the use of fossil fuels as an energy source has been trending downward. Many factors have contributed to this trend. For example, it has long been recognized that the use of fossil fuel-based energy options, such as oil, coal, and natural gas, produces gases and pollution that may not be easily removed from the atmosphere. Additionally, as more fossil fuel-based energy is consumed, more pollution is discharged into the atmosphere causing harmful effects on life close by. Despite these effects, fossil-fuel based energy options are still being depleted at a rapid pace and, as a result, the costs of some of these fossil fuel resources, such as oil, have risen. Further, as many of the fossil fuel reserves are located in politically unstable areas, the supply and costs of fossil fuels have been unpredictable.

Due in part to the many challenges presented by these traditional energy sources, the demand for alternative, clean energy sources has increased dramatically. To further encourage solar energy and other clean energy usage, some governments have provided incentives, in the form of monetary rebates or tax relief, to consumers willing to switch from traditional energy sources to clean energy sources. In other instances, consumers have found that the long-term savings benefits of changing to clean energy sources have outweighed the relatively high upfront cost of implementing clean energy sources.

One form of clean energy, solar energy, has risen in popularity over the past few years. Advancements in semiconductor technology have allowed the designs of solar modules and solar panels to be more efficient and capable of greater output. Further, the materials for manufacturing solar modules and solar panels have become relatively inexpensive, which has contributed to the decrease in costs of solar energy. As solar energy has increasingly become an affordable clean energy option for individual consumers, solar module and panel manufacturers have made available products with aesthetic and utilitarian appeal for implementation on residential structures. As a result of these benefits, solar energy has gained widespread global popularity.

### SUMMARY

The present disclosure is directed to a solar module including a plurality of strips, each strip including at least one bus bar formed on a top surface thereof, electrically conductive adhesive electrically connecting each strip when applied to the strip and the strips are arranged to overlap one another to connect the strips in series, and at least one string of overlapped strips, wherein the portable solar module has an output of less than about 200 Watts (W) and an output voltage of not less than about 5 Volts (V). The portable solar module may have an output of not less than about 100 W and 12 V, not less than about 5 W and 5 V, or not less than about 2 W.

The portable solar module may include at least two strings separated by a hinge, and each string may include 18 strips. The hinge separates at least two halves of the portable solar module, and each half includes at least three strings of 18 strips. The strings on one half of the portable solar module are connected in parallel with each other and the halves of the portable modules may be connected in series with one another. The output of the portable solar module may be at least 100 W and 12V.

In a further embodiment, the strings on one half of the portable solar module are connected in parallel with one another, and the strings in each half of the portable solar module are connected either in series or parallel.

A further embodiment of the present disclosure is directed to a method of manufacturing a portable solar module including singulating a solar cell to form a plurality of strips, each strip including at least a portion of bus bar, cutting the strips to form a plurality of solar squares, each square including at least a portion of the bus bar on at least one side of the solar square, and applying electrically conductive adhesive (ECA) to the plurality of solar squares. The method further includes overlapping a desired number of solar squares such that the ECA bonds the busbar of one cell to a second surface of an adjacent solar square to form a row of solar squares, arranging the rows of solar squares in a desired pattern, and electrically connecting the rows of solar squares to achieve a desired output power and voltage.

The method may further include electrically connecting the rows of solar squares in series or in parallel. And the desired number of squares is 10 and the output of the portable solar module is about 2 W.

### BRIEF DESCRIPTION OF THE DRAWINGS

Various aspects of the present disclosure are described hereinbelow with reference to the drawings, which are incorporated in and constitute a part of this specification, wherein:

FIG. 1 is a top view of a solar cell in accordance with the present disclosure;

FIG. 2 is a bottom view of a solar cell in accordance with the present disclosure;

FIG. 3 is a flow chart outlining a method of forming a string of strips in accordance with the present disclosure;

FIG. 4 is a schematic view of a scribing system in accordance with the present disclosure;

FIG. 5 is a top view of a singulated solar cell in accordance with the present disclosure;

FIG. 6 is a side view of shingled solar cell strips in accordance with a present disclosure;

FIG. 7 is a top view of a string of rectangular strips in accordance with the present disclosure;

FIG. 8 is a top view of a string of chamfered strips in accordance with the present disclosure;

FIG. 9 is depicts the processing steps of converting a solar cell to a solar module in accordance with the present disclosure;

FIG. 10 is depicts the processing steps of converting a solar cell to a solar module in accordance with a further aspect of the present disclosure;

FIG. 11 is depicts the processing steps of converting a solar cell to a solar module in accordance with two separate aspects of the present disclosure;

Further details and aspects of exemplary embodiments of the present disclosure are described in more detail below with reference to the appended figures.

### DETAILED DESCRIPTION

The present disclosure is directed to shingled solar modules and particularly portable solar modules. While there have been a variety of applications teaching the methods of formation and structure of a shingled array module (SAM), these have been directed at SAMs for use in industrial and solar power plant applications. Generally, these SAMs have an output of about 300 Watts. SAMs have the benefit of an increased output and efficiency as compared to traditional solar modules. These increases in output and efficiency are based largely on the increased total surface area available for absorption of sunlight as compared to traditional solar modules. While these SAMs are indeed of great benefit and superior to traditional solar modules, they are awkwardly sized and poorly fit for use in more portable applications such as on recreational vehicles, yachts, or even personal solar charging devices.

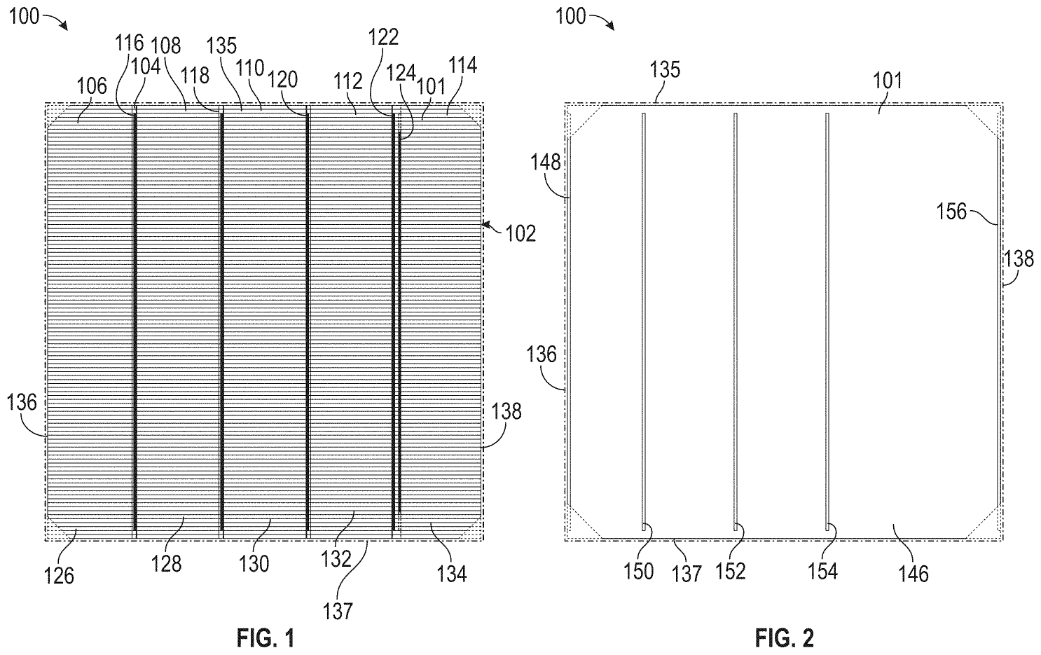

The general process for forming a SAM is described with respect to FIGS. 1-8. With reference to FIGS. 1-2, various views of a solar cell 100 are provided, according to an embodiment of the present disclosure. The solar cell 100 is made up of a substrate configured to be capable of producing energy by converting light energy into electricity. Examples of suitable photovoltaic material include, but are not limited to, those made from multicrystalline or monocrystalline silicon wafers. These wafers may be processed through the major solar cell processing steps, which include wet or dry texturization, junction diffusion, silicate glass layer removal and edge isolation, silicon nitride anti-reflection layer coating, front and back metallization including screen printing, and firing. The wafers may be further processed through advanced solar cell processing steps, including adding rear passivation coating and selective patterning to thereby obtain a passivated emitter rear contact (PERC) solar cell, which has a higher efficiency than solar cells formed using the standard process flow mentioned above. The solar cell 100 is a p-type monocrystalline cell, in an embodiment, but may be a p-type multicrystalline or an n-type monocrystalline cell in other embodiments. Similar to the diffused junction solar cells described as above, other high efficiency solar cells, including heterojunction solar cells and bifacial solar cells, can utilize the same or similar metallization patterns in order to be used for the manufacture of a shingled array module. The solar cell 100 may have a substantially square shape with chamfered corners (a pseudo-square) or a full square shape. As illustrated in the figures, these options are depicted with dashed lines showing the alternative configurations.

As illustrated in FIG. 1, the solar cell 100 has a metallization pattern 102 formed on a front side 104. The metallization pattern 102 generally includes a plurality of discrete sections 106, 108, 110, 112, 114, each of which has a front side bus bar 116, 118, 120, 122, 124 and finger lines 126, 128, 130, 132, 134. The discrete sections 106, 108, 110, 112, 114 are patterned such that, as will be described later, each discrete section 106, 108, 110, 112, 114 can be separated or singulated from the solar cell 100 to form a strip. As such, the sections 106, 108, 110, 112, 114 may be separated by a gap, which serves as a portion of the solar cell 100 at which a break may be made. The width of the gap, if included, is in a range of about 0.2 mm to about 2.0 mm. Here, five discrete sections 106, 108, 110, 112, 114 are included to thereby form five strips total. The front side bus bars 116, 118, 120, 122, 124 are substantially parallel to each other, and each extends along a length of the solar cell 100 without intersecting the top and bottom edges 135, 137 of the solar cell 100.

A back side 146 of the solar cell 100 likewise includes metallization, as illustrated in FIG. 2. In an embodiment, the back side 146 includes a plurality of back side bus bars 148, 150, 152, 154, 156, the total number of which is equal to the number of front side bus bars 116, 118, 120, 122, 124. Each back side bus bar 148, 150, 152, 154, and 156 corresponds to a discrete section 106, 108, 110, 112, 114. In an embodiment, the location of each back side bus bar 148, 150, 152, 154, and 156 depends on the location of a corresponding front side bus bar 116, 118, 120, 122, 124. Specifically, upon cleaving the solar cell 100 into a plurality of strips, each strip has a front side bus bar 116, 118, 120, 122, 124 on an edge opposite from an edge on which a back side bus bar 148, 150, 152, 154, 156 is formed.

The particular locations of the front and back side bus bars are strategically selected. In particular, the front side bus bars may be formed at locations that are away from one or both of the edges of the solar cell 100, which thereby reduces side leakage and improves shunt resistance. As a result, high yield and improved low irradiation performance are achieved. Furthermore, by grouping two of the front side bus bars together so that they are adjacent each other, three sets of probes may be employed, rather than the typical five or six sets of probes, to contact bus bars during flash testing. The fewer number of probes used also reduces the shadow impact of the probes during the testing to thereby improve the accuracy and consistency of cell efficiency test.

The back side bus bars 148, 150, 152, 154, 156 are unevenly spaced apart across the solar cell 100. Specifically, the back side bus bars 148, 150, 152, 154, 156 are formed at locations on the back side 146 of the solar cell 100 such that upon cleaving the solar cell 100 into a plurality of strips made up of each of the discrete sections 106, 108, 110, 112, 114, the front side bus bar 116, 118, 120, 122, 124 of the strip is on an edge opposite from an edge on which a back side bus bar 148, 150, 152, 154, 156 is formed. For example, turning to FIG. 2, back side bus bar 148 is formed along the left edge 136 of the solar cell 100, while back side bus bar 156 is formed along the right edge 138 of the solar cell 100. Back side bus bars 150, 152, 154 are formed along a left edge of corresponding discrete sections 108, 110, 112.

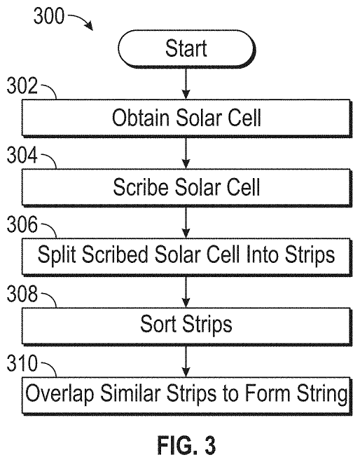

Having produced or been provided a solar cell 100, the process of building a SAM can begin. With reference to FIG. 3, a solar cell is obtained at step 302 of method 300. In an embodiment, the solar cell is tested, for example, using flash testing. In embodiments of solar cells including 5 strips, by grouping two bus-bars adjacent each other on the front side of the solar cell, three sets of probes can be used to contact bus-bars in flash testing, which may reduce the impact of shadow produced by the probes when a light is shined on the solar cell. Similarly, in embodiments in which 6 strips are included, by grouping two bus-bars adjacent each other, only five sets of probes may be used in flash testing instead of six sets of probes; alternatively, by grouping two bus-bars adjacent each other, only four sets of probes (rather than six sets of probes) may be used in flash testing.

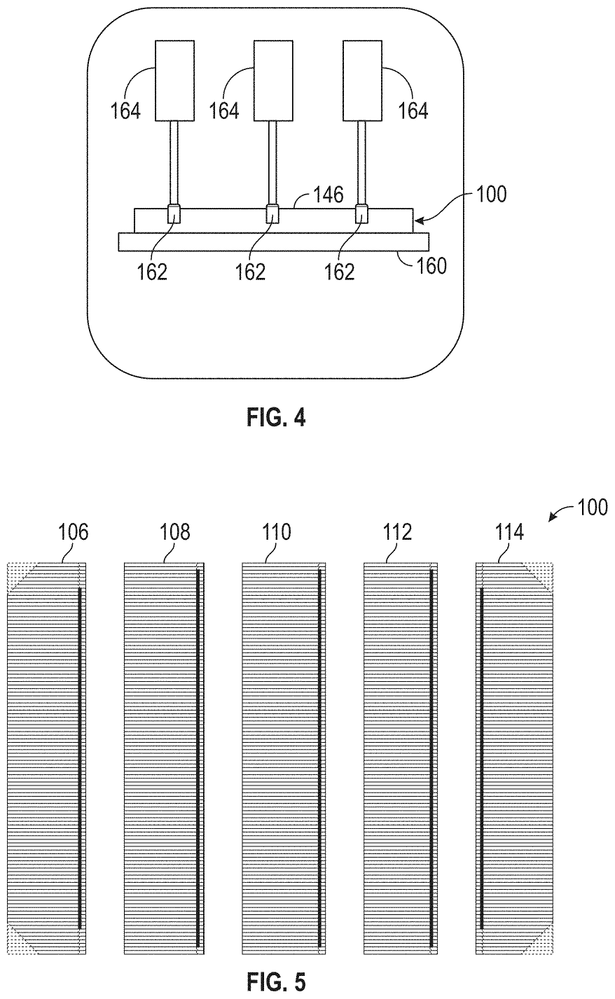

The solar cell is cut at step 304. Specifically, scribe lines are formed into the back surface of the solar cell so that when the solar cell is broken, the split occurs in the gap on the front surface of the solar cell between the discrete cells. Each scribe line has a depth of between about 10% and about 90% of wafer thickness. In an embodiment, the scribe lines extend across the solar cell from edge to edge. In another embodiment, one or both of the scribe lines extends from one edge to just short of an opposite edge of the solar cell. The scribe lines may be formed using a laser, a dicing saw and the like. In an embodiment, as illustrated in FIG. 4, a solar cell 100 is placed on a platform 160 back side 146 facing up so that scribe lines 162, may be formed in the solar cell 100. One or more lasers 164 are aligned at locations on the solar cell to form the scribe lines 162 along which the solar cell 100 will be singulated into strips.

Next, the scribed solar cell 100 is split at step 306. In an embodiment in which the solar cell may be singulated, the solar cell is placed on a vacuum chuck including a plurality of fixtures which are aligned adjacent each other to form a base. The vacuum chuck is selected so that the number of fixtures matches the number of discrete sections of the solar cell to be singulated into strips. Each fixture has apertures or slits, which provide openings communicating with a vacuum. The vacuum, when desired, may be applied to provide suction for mechanically temporarily coupling the solar cell to the top of the base. To singulate the solar cell, the solar cell is placed on the base such that the each discrete section is positioned on top of a corresponding one of the fixtures. The vacuum is powered on and suction is provided to maintain the solar cell in position on the base. Next, all of the fixtures move relative to each other. In an embodiment, multiple ones of the fixtures move a certain distance away from neighboring fixtures thereby causing the discrete sections of the solar cell to likewise move from each other and form resulting strips. In another embodiment, multiple ones of the fixtures are rotated or twisted relative to their longitudinal axes thereby causing the discrete sections of the solar cell to likewise move and form resulting strips. The rotation or twisting of the fixtures may be effected in a predetermined sequence, in an embodiment, so that no strip is twisted in two directions at once. In still another embodiment, mechanical pressure is applied to the back surface of the solar cell to substantially simultaneously break the solar cell into the strips. It will be appreciated that in other embodiments, other processes by which the solar cell is singulated alternatively may be implemented. Upon completion of singulation in step 306, the solar cell 100 is separated into its sections or strips 106-114 as shown in FIG. 5

After the solar cell is singulated, the strips are sorted in step 308. In particular, as shown in FIG. 5, the left-most and right-most strips 106 and 114, may have chamfered corners and, as a result, have dimensions that are different from strips 108, 110, and 112, which have non-chamfered corners and substantially identical dimensions. In an embodiment, sorting strips is achieved using an auto-optical sorting process. In another embodiment, the strips are sorted according to their position relative to the full solar cell. After sorting, strips 106, 114 having chamfered corners are segregated from those strips 108, 110, 112 having non-chamfered corners. During sorting, strips can be arranged to align the bus bars into desired positions.

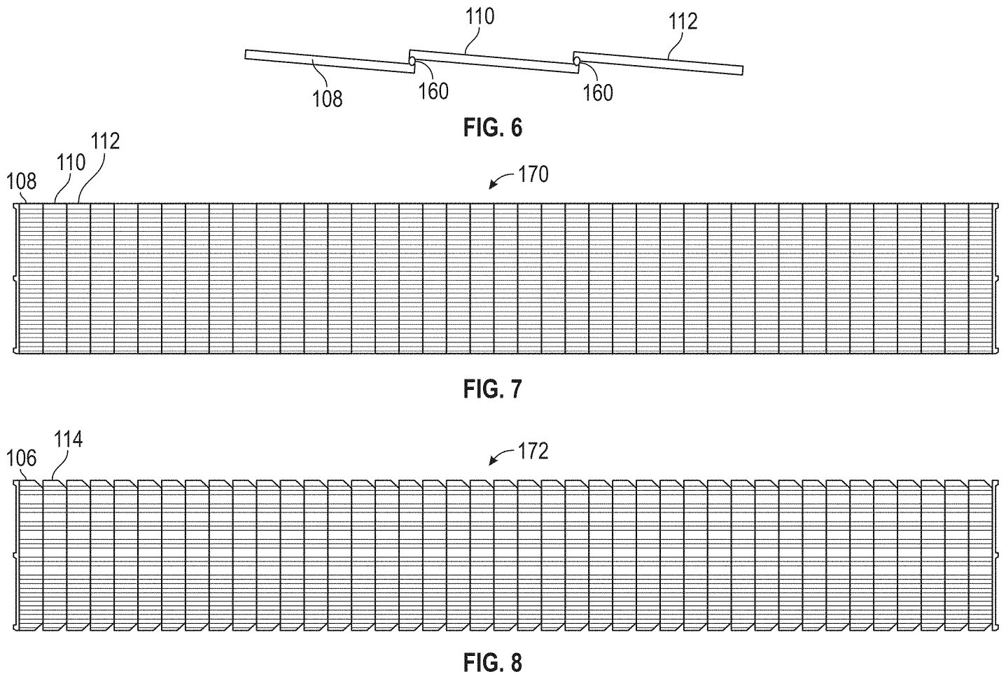

With continued reference to FIG. 3 and FIG. 6, similarly dimensioned strips are then placed in an overlapping arrangement to form a string in step 310. In an embodiment, an electrically-conductive adhesive 160 is applied to a front surface of the strip 108 along an edge including the front side bus bar 118 (FIG. 1). In another embodiment, the electrically-conductive adhesive is applied to a backside 146 surface of the strip 108, in at least one embodiment along the back side bus bar 150. The adhesive may be applied as a single continuous line, as a plurality of dots, dash lines, for example, by using a deposition-type machine configured to dispense adhesive material to a bus bar surface. In an embodiment, the adhesive is deposited such that it is shorter than the length of a corresponding bus bar and has a width and thickness to render sufficient adhesion and conductivity. After the adhesive is deposited onto the strip 108, the strip 108 and a second, similarly dimensioned strip 110 are aligned such that the back side bus bar of one strip 110 overlaps with the front side bus bar of the other strip 108, or alternatively, the front side bus bar of one strip overlaps with the back side bus bar of another. The steps of applying adhesive and aligning and overlapping the strips are repeated until a desired number of strips are adhered to form the string 170 (FIG. 7), or a string 172 (FIG. 8). The string 172 is formed of the strips 106 and 114 formed with the chamfered edges. Although step 310 is described as being performed on two strips, one or both of the strips may be pre-adhered to one or more other strips.

In an embodiment as illustrated in FIG. 7, non-chamfered strips 108, 110, and 112 are adhered to each other to form a string 170. The string includes 15 to 100 strips and each strip is overlapped such that the back side bus bar of each strip overlaps and is disposed over the front side bus bar of an adjacent strip, as depicted in FIG. 6. The string 170 of FIG. 7 also includes electrical connections for coupling to another similarly configured string. An end of the string 170 includes a metal foil soldered or electrically connected to the bus bar of each end strip which will be further connected to a module interconnect bus bar so that two or more strings together form the circuit of a solar module, as will be discussed in detail in subsequent paragraphs below. In another embodiment, the module interconnect busbar can be directly soldered or electrically connected to the bus bar of the end strip to form the circuit.

FIG. 8 illustrates another embodiment, a string 172 of chamfered corner strips 106, 114 where the back side bus bar of each strip 106, 114 overlaps and is disposed over the front side bus bar of an adjacent strip. Again, 15 to 100 strips make up the string 172.

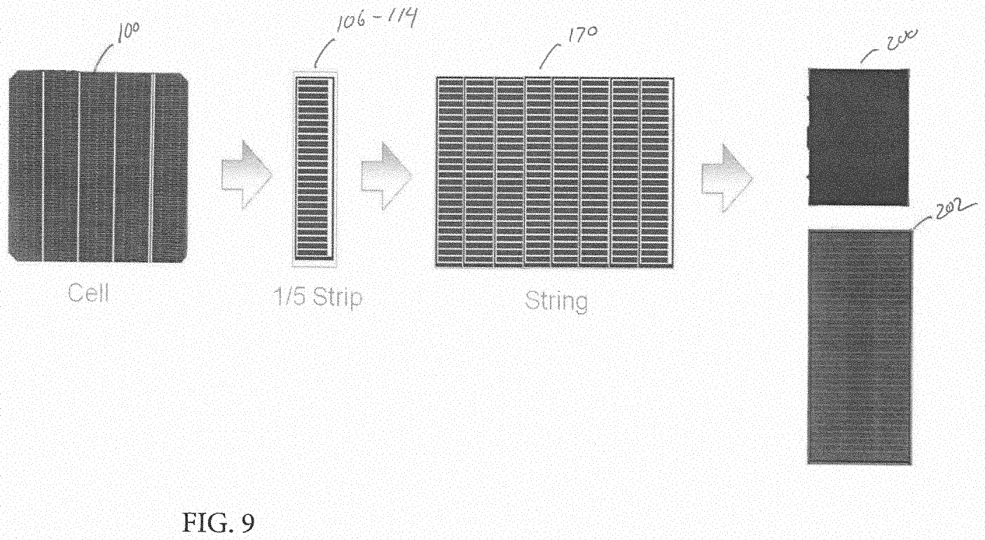

FIGS. 9-11 depict various aspects of the present disclosure related to the methods and structure of a portable SAM module. These methods and structure build on the above-described methods of forming strings and modules for solar cells. FIG. 9 depicts a cell 100 having five bus bars, as described in connection with FIG. 1. This cell can be processed to form strips 106-114 of ⅕^{th} of the width of the cell 100. Each strip 106-114 may include a bus bar on each side as depicted above, or other configurations as described in detail in one or more of the references incorporated herein by reference. These strips 106-114 may then be assembled in to strings as shown.

As is known in the art any solar cell, or portion thereof, regardless of the size is approximately 0.6 volts. Thus both the cell depicted in FIG. 9 and the strip each have an output of approximately 0.6 V. Accordingly, the number of strips 106-114 that are connected in series will determine the voltage output of the cell. Similarly, the current output (and thus the power in Watts) is proportional to the surface area of the solar cells. Accordingly, it is possible to design a solar module having a desired power output. A common output for portable solar modules is 100 W. These 100 W portable solar modules 200, 202 typically take two forms, one is a fixed flat module 202 that may include legs to prop the solar module at an orientation facing the sun, or may be designed to lay flat on a support structure such as the roof of a recreational vehicle or a yacht. A further configuration that can be particularly useful because of its smaller stowed size is a folded solar module 200, where the solar module 202 has a hinge allowing the solar module to be folded in half, typically on its long axis, and take a form that is easier to stow away, similar to a briefcase.

In order to charge typical lead acid batteries a charge voltage of about 14-16 volts is necessary. In order to achieve the desired voltage it is necessary that the input to a charge controller (i.e., the output of the solar module) be approximately 18-19V, and will be stepped down in the charge controller to the desired 14-16V charge voltage. As will be appreciated there are additional degradations of the output of the solar module over time, thus a convenient design criteria is to design the solar module to output 20V and 100 W of power.

In the context of a fixed flat solar module 202 to output 20V, 33 strips 106-114 must be connected in series as described above. Then three strings 170 of strips 106-114 can be connected in parallel to output the desired 100 W. If an output current of 130 W is desired then four strings 170 must be connected in parallel. For the folded portable module 200 design, a different configuration is necessary. First because of the one or more hinges, the total length of the string 170 can only be about half (or ⅓, ¼, ⅕, ⅙^{th}) of the length of the solar module once unfolded. In the context of a ½ folded solar module 200, each string 170 will have approximately 18 strips. While this is somewhat more than half the needs of a fixed flat solar module 202, the additional strips are necessary to account for losses created by the wiring of the two halves to one another. As a result a 100 W folded solar module will have three strings 170 of 18 strips 106-114. The strips 106-114 are connected in series to form the string 170 as described above. A string 170 of 18 strips will output approximately 10V. The strings 170 of the first half of the solar module 200 are connected in series with the strings 170 of the second half of the solar module, resulting in a string output total of approximately 20V. The two sets of three strings 170 are connected in parallel and output about 100 W. If four strings 170 are utilized the output is approximately 130 W. The portable SAMs 200 and 202 are particularly useful in recreational vehicle yachts for charging batteries.

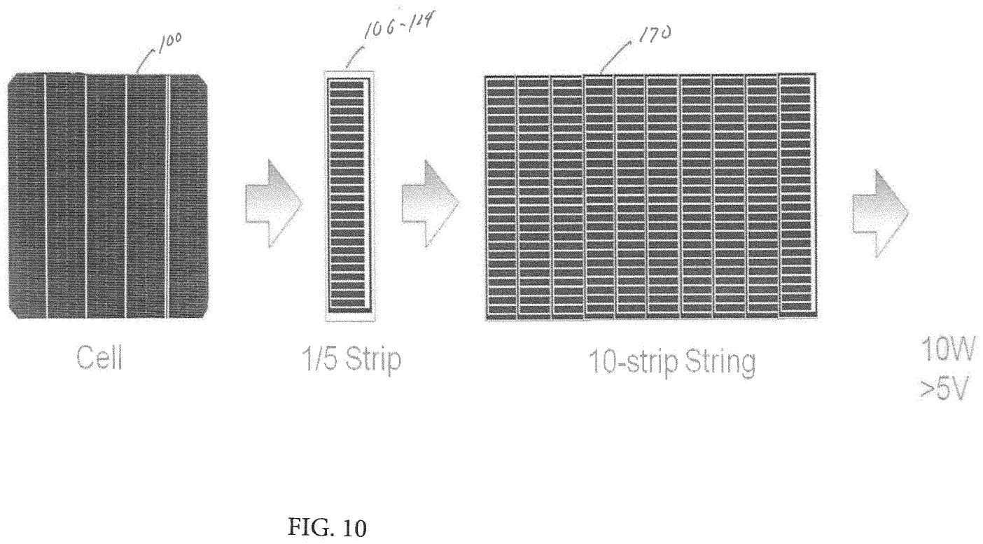

A further embodiment of the present disclosure can be seen with respect to FIG. 10. As with the embodiment of FIG. 9, the cell is singulated to produce strips. However, for a portable charging device such as may be attached to a purse, backpack, or other application need not output 100 W but rather most chargers have an output of just 10 W and about 5V. To create such a SAM, 10 strips 106-14 need to be connected in series as shown in FIG. 10. The 10 strip string 170 may be encapsulated and secured within a housing to allow for ease of connection to a backpack or the like and for connecting power output connection whereby portable electronic devices may be connected to the SAM. As above, each strip 106-114 outputs about 0.6V so when 10 are combined in series the output is approximately 6V, which again can be stepped down by the charge controller to 5V for charging most portable electronics including cell phones, laptop computer, tablets, security cameras, yard lights.

Though depicted in FIG. 10 as having the same dimensions as the strips 106-114 for the solar modules of FIG. 9, other options for the formation of the strips can also be employed. In one example, where the desired output of the SAM is smaller, for example 2 W a single solar cell 101 may be employed and cut into 20 strips 206. A string 270 that is a combination of −10 the 1/20^{th} strips 206, when combined in a SAM will produced 5V (0.6V per strip) and approximately 2 W of power. Such a configuration may be particularly useful for very small chargers and again, the SAM may be encapsulated and formed with a housing surrounding the SAM for security and safety and power output connections.

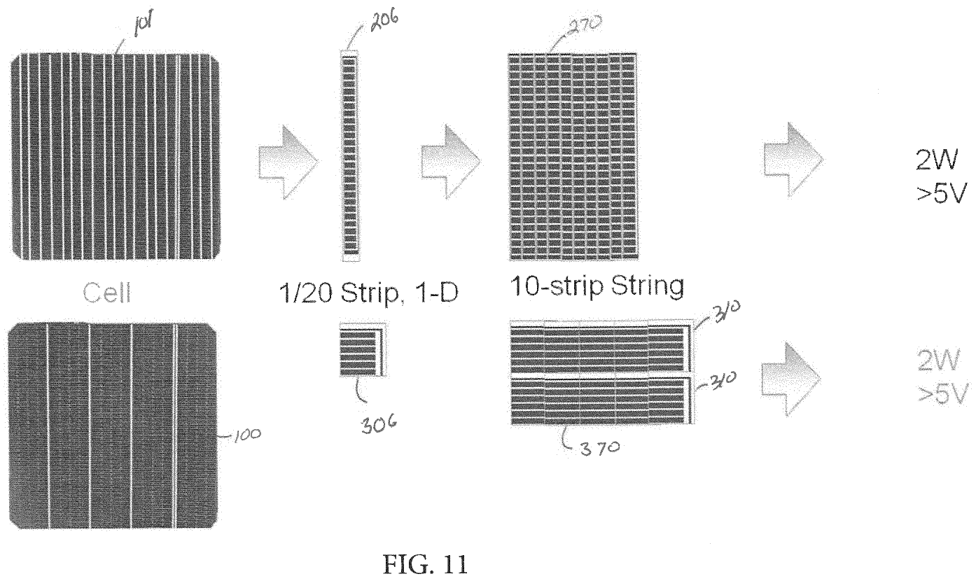

An alternative to cutting the solar cell into 20 strips is to cut the solar cell into 5 strips as in the other embodiments if the present disclosure, and then cut each strip 106-114 into four generally square pieces 306, as depicted in FIG. 11. Though depicted here as singulating along the bus bars 116-124 (i.e., parallel to the bus bars), those of skill in the art will recognize that singulation may occur normal to the bus bars such that each strip 106-114 has at least one sections of each of the bus bars 116-124. Again, because each cell regardless of size output approximately 0.6V, the ultimate size of the cell does not affect the output voltage of the cell thus square 306 outputs approximately 0.6V. Again connection of all 10 of the solar squares 306 in series (e.g., two rows 310 of 5 squares 306 connected via shingling, and the two rows 310 connected in series via a wire, cable, trace or the like produces a SAM that outputs 2 W of power at 6V. This second approach has some benefits over the formation of 1/20^{th} strips 206 as the starting solar cell 100 does not require 20 bus bars as does solar cell 101. The additional bus bars reduce the amount of silicon available for the conversion of sunlight to electricity. The second approach also experiences less metal shading, and the cutting of the cell is easier to control. Still further the square strips provide some greater design flexibility.

Though described herein as having a specific number of strips and strings, each SAM may be formed of a variety of strips and strings without departing from the scope of the present disclosure depending on the application. Thus strings of 5, 10, 15, 20, 25, 30, 35, 40, 45, 50, 55, 60, 65, 70, 75, 80, 85, 90, 95, 100 or more strips and any number therein between to achieve a desired output voltage and power are contemplated within the scope of the present disclosure. Further SAMs having 1, 2, 3, 4, 5, 6, 7, 8, 9, 10, 11, 12, 13, 14, 15, 16, 17, 18, 19 or 20 strings have the number of strips described above are contemplated within the scope of the present disclosure to achieve a desired output voltage and power. Similarly the formation of series connected squares can also vary from 2-100, and any number therein between, and can be formed in parallel rows in any number from 2-100 as desired by the designer for a specified or desired voltage and power rating.

While several embodiments of the disclosure have been shown in the drawings, it is not intended that the disclosure be limited thereto, as it is intended that the disclosure be as broad in scope as the art will allow and that the specification be read likewise. Any combination of the above embodiments is also envisioned and is within the scope of the appended claims. Therefore, the above description should not be construed as limiting, but merely as exemplifications of particular embodiments. Those skilled in the art will envision other modifications within the scope of the claims appended hereto.

1. A portable solar module comprising:
a plurality of strips, each strip including at least one bus bar formed on a top surface thereof;
electrically conductive adhesive electrically connecting each strip when applied to the strip and the strips are arranged to overlap one another to connect the strips in series;
at least one string of overlapped strips, wherein the portable solar module has an output of less than about 200 Watts (W) and an output voltage greater than about 5 Volts (V).

2. The portable solar module of claim 1, wherein the portable solar module has an output of not less than about 100 W and not less than about 12 V.

3. The portable solar module of claim 1, wherein the portable solar module has an output of less than about 5 W and an output of not less than 5V.

4. The portable solar module of claim 1, wherein the portable solar module has an output of less than about 2 W.

5. The portable solar module of claim 1, further comprising at least two strings separated by a hinge.

6. The portable solar module of claim 5, wherein each string includes 18 strips.

7. The portable solar module of claim 5, wherein the hinge separates two halves of the portable solar module, and each half includes at least three strings of 18 strips.

8. The portable solar module of claim 7, wherein the strings on one half of the portable solar module are connected in parallel with each other.

9. The portable solar module of claim 8, wherein the two halves of the portable solar module are connected in series with one another.

10. The portable solar module of claim 9, wherein the output of the portable solar module is at least 100 W and 12V.

11. The portable solar module of claim 5, wherein the strings on one half of the portable solar module are connected in parallel with one another.

12. The portable solar module of claim 11, wherein the strings in each half of the portable solar module are connected either in series or parallel.

13-18. (canceled)
